(19) United States
(12) Patent Application Publication
(10) Pub. No.: US 2026/0231354 A1
(43) Pub. Date: Aug. 6, 2026

(54) BACKFLOW PREVENTION DEVICE

(71) Applicant: NIDEC PRECISION CORPORATION, Tokyo (JP)

(72) Inventor: Masakatsu ICHIHARA, Tokyo (JP)

(21) Appl. No.: 19/149,845

(22) PCT Filed: Jan. 11, 2024
(86) PCT No.: PCT/JP2024/000460

§ 371 Date: Jul. 22, 2025

(30) Foreign Application Priority Data
Jan. 27, 2023 (JP) 2023-010714

(51) Int. Cl. H05K 7/20; G06F 1/20

(52) U.S. Cl. CPC H05K 7/2019; G06F 1/20; H05K 7/20145; H05K 7/20172; G06F 2200/201

(57) ABSTRACT

A backflow prevention device attachable to a fan device includes a body having an opening through which air passes in response to rotation of the fan device about the rotation axis, a compartment adjacent to a central portion of the opening, multiple blades housed in the compartment in a drivable manner, and a drive that drives the blades to rotate on an intersecting plane intersecting with an axial direction. The air flows in the axial direction in which a rotation axis of the fan device extends. The drive switches the blades between a housed state in which the blades are housed in the compartment and a closing state in which the blades close the opening. In the housed state, at least two blades partially overlap each other in the axial direction and are housed in the compartment.

### RELATED APPLICATIONS

The present application is National Phase of International Application Number PCT/JP2024/000460, filed Jan. 11, 2024, and claims priority based on Japanese Patent Application No. 2023-010714, filed Jan. 27, 2023.

### FIELD

The present invention relates to a backflow prevention device.

### BACKGROUND

Electronic devices that operate continuously, such as servers, are to have redundancy. Multiple fan devices are thus used to cool an electronic device. When one of the fan devices has a failure, the rotational speed of the remaining fan devices is increased to maintain the cooling performance. The fan devices have a backflow prevention function to reduce the likelihood that the cooling effect on the electronic device is reduced due to backflow air or the likelihood that the fans rotate backward due to air passing through during replacement of a fan device with a failure, causing a fault such as a sensor malfunction.

Patent Literature 1 describes a cooling fan system with a wind-pressure shutter including multiple flaps. The multiple flaps are attached to be slightly inclined with respect to the direction of an air passage. During the normal operation of the cooling fan system, the flaps in the wind-pressure shutter are substantially parallel to the direction of the air passage to have an open air passage. When the cooling fan system has a failure causing backflow air, the flaps attached to be inclined with respect to the air passage have their surfaces under the pressure of the backflow air. The flaps under the pressure rotate with support shafts as the pivots to close the air passage.

### CITATION LIST

### Patent Literature

Patent Literature 1: Japanese Unexamined Patent Application Publication No. 2011-231954

### BRIEF SUMMARY

### Technical Problem

In the wind-pressure shutter described in Patent Literature 1, the multiple flaps are movable along the air passage. Each flap is to be movable in a range along the air passage, thus increasing the size of the device.

### Solution To Problem

A backflow prevention device according to an aspect of the present invention is attachable to a fan device. The backflow prevention device includes a body having an opening through which air passes in response to rotation of the fan device about the rotation axis, a compartment adjacent to a central portion of the opening, and a plurality of blades housed in the compartment in a drivable manner. The air flows in an axial direction in which a rotation axis of the fan device extends. A drive drives the plurality of blades to rotate on an intersecting plane intersecting with the axial direction, and switches the plurality of blades between a housed state in which the plurality of blades are housed in the compartment and a closing state in which the plurality of blades close the opening. In the housed state, at least two of the plurality of blades overlap each other in the axial direction and are housed in the compartment.

### Advantageous Effects

The technique according to the above aspect of the present invention can reduce the size of the backflow prevention device that prevents backflow air from entering the fan device.

### BRIEF DESCRIPTION OF DRAWINGS

FIG. 1 is an external perspective view of a backflow prevention device according to an embodiment.

FIG. 2 is an external perspective view of the backflow prevention device.

FIG. 3 is an exploded perspective view of the backflow prevention device.

FIG. 4 is an external plan view of a blade.

FIG. 5 is a cross-sectional view of the backflow prevention device taken along line A-A in FIG. 1.

FIG. 6A is a diagram of a first body, a first compartment, and a closure in a first state as viewed from downstream.

FIG. 6B is a diagram of the first body, the first compartment, and the closure in a second state as viewed from downstream.

FIG. 7 is a schematic block diagram of the backflow prevention device and a fan device, showing their main components.

### DETAILED DESCRIPTION

A backflow prevention device according to one or more embodiments of the present invention will now be described in detail with reference to the drawings.

The backflow prevention device is attached to each of multiple fan devices that blow cooling air toward, for example, an electronic device (cooling target) such as a server. When, for example, any one of the fan devices has a failure and does not operate, the corresponding back flow prevention device blocks an air passage through which cooling air flows, thus preventing cooling air entering through the fan devices with no failure from being discharged outside through the fan device with a failure. The operation state of the backflow prevention device is thus switchable between a first state in which the backflow prevention device does not block the passage of cooling air with the fan device having, for example, no failure, and a second state in which the backflow prevention device blocks the passage of cooling air in response to the fan device having, for example, a failure.

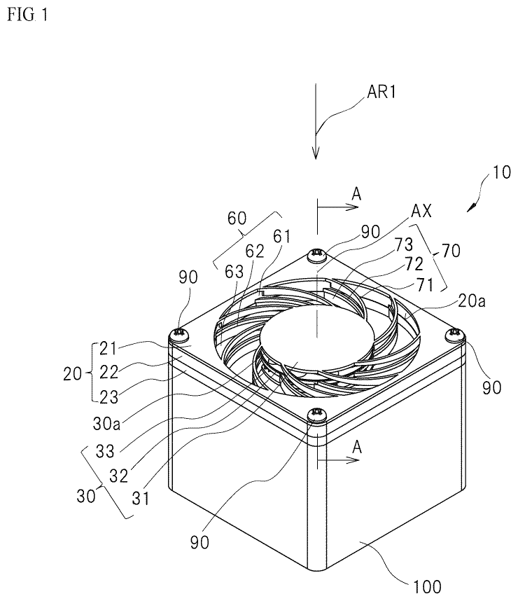

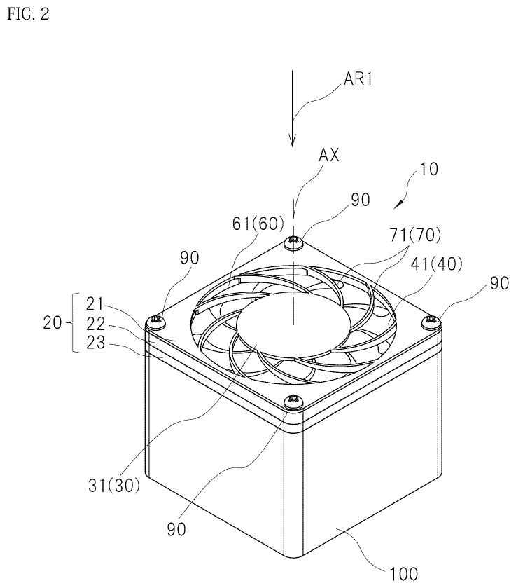

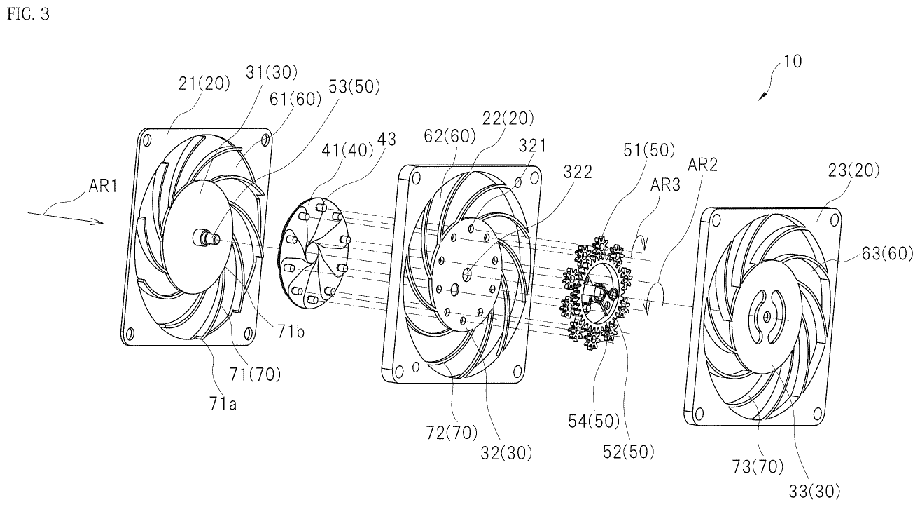

Overall Structure of Backflow Prevention Device FIGS. 1 and 2 are external perspective views of a fan device 100 and a backflow prevention device 10 attached to the fan device 100. FIG. 1 shows the backflow prevention device 10 in the first state in which the passage of cooling air is not blocked. FIG. 2 shows the backflow prevention device 10 in the second state in which the passage of cooling air is blocked. The fan device 100 includes a fan rotatable about a rotation axis AX shown in FIGS. 1 and 2. The fan rotates to cause air to flow in the direction of arrow AR1 (hereafter referred to as an axial direction AR1) in which the rotation axis AX extends. FIG. 3 is an exploded perspective view of the backflow prevention device 10 in the first state.

In FIGS. 1 to 3, the backflow prevention device 10 is located upstream from the fan device 100. However, the backflow prevention device 10 may be located downstream from the fan device 100. The backflow prevention device 10 includes a body 20, a compartment 30, a closure 40, and a drive 50.

### Body 20

The body 20 has a rectangular cross section on a plane (hereafter referred to as an intersecting plane) intersecting with (perpendicular to) the axial direction AR1. The body 20 is a rectangular prism extending in the axial direction AR1. The body 20 may not have a rectangular cross section on the intersecting plane, and may have a cross section with a shape based on the cross section of the fan device 100 to which the backflow prevention device 10 is attached.

The body 20 includes a first body 21, a second body 22, and a third body 23 in the axial direction AR1. The first body 21 is located upstream in the axial direction AR1. The second body 22 is located downstream from the first body 21. The third body 23 is located downstream from the second body 22. The first body 21, the second body 22, and the third body 23 are attached to and fastened to the fan device 100 with screws 90.

The first body 21 has an opening 61, the second body 22 has an opening 62, and the third body 23 has an opening 63 on the intersecting plane. In the first state, the openings 61, 62, and 63 function as air tunnels through which air (cooling air) flowing in the axial direction AR1 passes in response to rotation of the fan device 100 about the rotation axis AX. The openings 61, 62, and 63 may be hereafter collectively referred to as an opening 60. The compartment 30 having surfaces intersecting with (perpendicular to) the axial direction AR1 is located adjacent to a central portion of the opening 60.

### Compartment 30

The compartment 30 is located adjacent to the central portion of the opening 60 as described above. In other words, the opening 60 is defined by an inner wall surface 20a of the body 20 and an outer wall surface 30a of the compartment 30. The closure 40 (described in detail later) is housed in the compartment 30 in a manner spreadable in the opening 60. The drive 50 (described in detail later) is located in the compartment 30. The compartment 30 is supported by the body 20 with supports 70 (described in detail later).

More specifically, the compartment 30 includes a first compartment 31, a second compartment 32, and a third compartment 33. The first compartment 31 is supported by the first body 21 with multiple first supports 71 included in the supports 70. The second compartment 32 is supported by the second body 22 with multiple second supports 72 included in the supports 70. The third compartment 33 is supported by the third body 23 with multiple third supports 73 included in the supports 70.

The first compartment 31 is a disk having a smaller diameter than the opening 60 (opening 61). The closure 40 is located downstream from the first compartment 31. The first compartment 31 is sized to cover, on the intersecting plane, a larger area than the closure 40 in the first state (housed state) in which the closure 40 (described later) is housed.

The second compartment 32 is a disk having a smaller diameter than the opening 60 (opening 62) and the same shape as the first compartment 31. The closure 40 is located upstream from the second compartment 32. The drive 50 is located downstream from the second compartment 32. The second compartment 32 has multiple through-holes 321 for attaching multiple blades 41 in the closure 40 (described later), and a through-hole 322 through which a second blade rotational shaft 53 of the drive 50 (described later) extends. The multiple through-holes 321 are arranged in the circumferential direction of the second compartment 32 on the intersecting plane. The through-hole 322 is located adjacent to the center of the second compartment 32.

The third compartment 33 is a disk having a smaller diameter than the opening 60 (opening 63) and the same shape as the first compartment 31 and the second compartment 32.

### Closure 40

The closure 40 includes the multiple blades 41 that close the opening 60 (opening 61). The closure 40 in the present embodiment includes ten blades 41 as shown in FIG. 3. The blades 41 may not be ten blades 41. The number of blades 41 is determined based on the size of the fan device 100, or specifically, the size of the opening 60. The blades 41 may thus be fewer than ten blades 41 or ten or more blades 41.

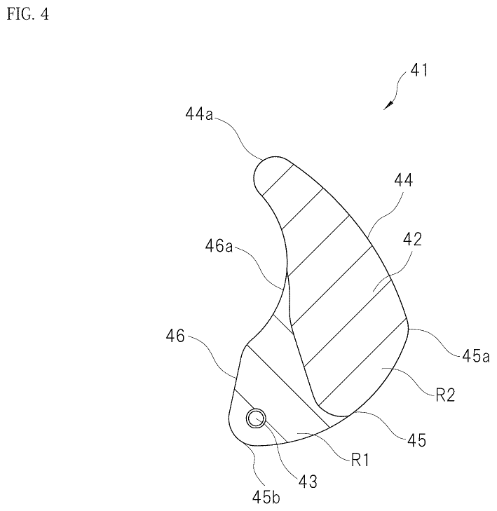

FIG. 4 is an external plan view of a single blade 41. The blade 41 is a thin plate formed from, for example, a resin or metal. The blade 41 has a surface 42 downstream in the axial direction AR1 on which a first blade rotational shaft 43 is located. The first blade rotational shaft 43 protrudes downstream in the axial direction AR1. The blade 41 is attached to the second compartment 32 to be drivable by the drive 50 (described later) using the first blade rotational shaft 43 as the rotation center. More specifically, the first blade rotational shaft 43 is placed through the corresponding through-hole 321 in the second compartment 32 from upstream and connected to the drive 50 downstream from the second compartment 32.

The blade 41 has a first wall surface 44, a second wall surface 45, and a third wall surface 46 as its edges. The first wall surface 44 extends along the circumference of the opening 60, or specifically, the inner wall surface 20a of the body 20, on the intersecting plane. In the second state (closing state), the first wall surface 44 of the blade 41 is in contact with the inner wall surface 20a of the body 20, which is the circumference of the opening 60. The second wall surface 45 adjoins the first wall surface 44 at an end 45a. The second wall surface 45 extends along the circumference of the outer wall surface 30a that is an edge of the compartment 30 on the intersecting plane. In the first state (housed state), the second wall surface 45 of the blade 41 is located downstream from the outer wall surface 30a that is an end of the compartment 30 in the axial direction AR1. The third wall surface 46 adjoins an end 44a of the first wall surface 44 and an end 45b of the second wall surface 45. The third wall surface 46 includes a curved portion 46a to avoid interference with the drive 50 located in the compartment 30 in the first state (housed state). The first blade rotational shaft 43 described above is located adjacent to the end 45b at which the second wall surface 45 and the third wall surface 46 connect to each other.

The blade 41 is curved with respect to the intersecting plane. More specifically, the blade 41 includes a first area R1 adjacent to the first blade rotational shaft 43 (in other words, adjacent to the end 45b) and a second area R2 including the first wall surface 44, a part of the second wall surface 45, and a part of the third wall surface 46. The second area R2 is raised upstream in the axial direction AR1 with respect to the first area R1. As described later, one blade 41 is housed in the compartment 30 with its second area R2 located upstream from the first area R1 of another blade 41 in the first state.

### Drive 50

The drive 50 is located on a downstream surface of the second compartment 32 as described above. As shown in FIG. 3, the drive 50 includes multiple first gears 51 and a second gear 52 meshing with each of the first gears 51.

The number of first gears 51 is the same as the number of blades 41. Each first gear 51 includes its center connected to the first blade rotational shaft 43 of the corresponding blade 41. As described above, the first blade rotational shafts 43 of the multiple blades 41 are placed through the respective through-holes 321 arranged in the circumferential direction of the second compartment 32. The first gears 51 are thus also arranged in the circumferential direction of the second compartment 32 (in other words, the compartment 30). Each first gear 51 has teeth arranged along its outer circumference.

The second gear 52 is annular and has a larger diameter than the first gears 51. The second gear 52 has teeth arranged along its outer circumference and meshing with the multiple first gears 51. In other words, the first gears 51 are arranged adjacent to the outer circumference of the second gear 52. The second gear 52 includes a support shaft 54 extending in the radial direction of the annular second gear 52. The support shaft 54 includes a middle portion having a through-hole receiving the second blade rotational shaft 53. The second blade rotational shaft 53 protrudes downstream from the center of the downstream surface of the first compartment 31 in the axial direction AR1. The second blade rotational shaft 53 extends through the through-hole 322 in the second compartment 32 and is placed through the through-hole in the support shaft 54. The second gear 52 is thus rotatable about the second blade rotational shaft 53.

As the second gear 52 rotates about the second blade rotational shaft 53, the multiple first gears 51 rotate. As the first gears 51 rotate, the blades 41 rotate about the first blade rotational shafts 43 connected to the centers of the respective first gears 51. In other words, the drive 50 located on the downstream surface of the second compartment 32 drives each of the multiple blades 41 to rotate on the intersecting plane. In this manner, the drive 50 switches the multiple blades 41 between the first state and the second state. The first state is the housed state in which the closure 40 does not close the opening 60 and the multiple blades 41 are housed in the compartment 30 as described above. The second state is the closing state in which the opening 60 is closed by the multiple blades 41.

The second gear 52 may not have the teeth arranged along its outer circumference, and may have the teeth arranged along its inner circumference. In other words, the multiple first gears 51 may be arranged adjacent to the inner circumference of the second gear 52.

### Support 70

The supports 70 connect the body 20 and the compartment 30 located adjacent to the central portion of the opening 60 in the body 20. The supports 70 support the compartment 30. The number of supports 70 is the same as the number of blades 41. Each of the multiple supports 70 is a curved rod extending along a path on which the corresponding blade 41 described above rotates on the intersecting plane.

The supports 70 include the first supports 71, the second supports 72, and the third supports 73 in the axial direction AR1. The first supports 71 connect the first body 21 and the first compartment 31. The second supports 72 connect the second body 22 and the second compartment 32. The third supports 73 connect the third body 23 and the third compartment 33.

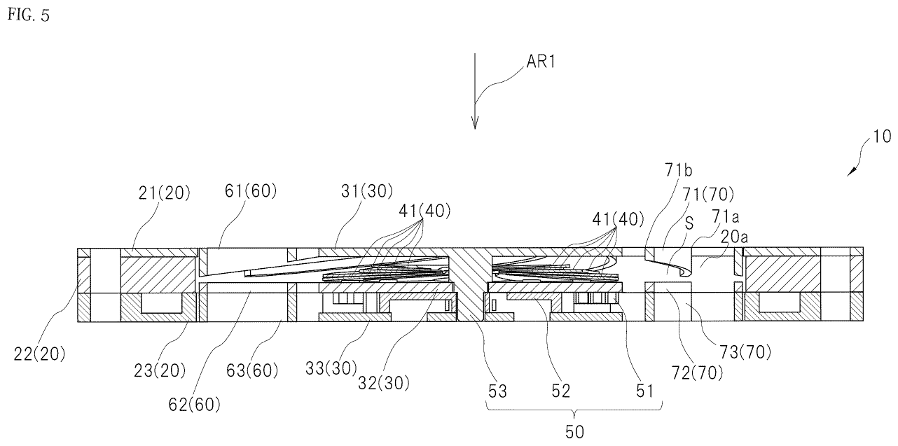

FIG. 5 is a cross-sectional view of the backflow prevention device 10 taken along line A-A in FIG. 1. The first supports 71 that are first portions in the supports 70 connect to the first compartment 31. The first supports 71 are thus located upstream (in a first direction) from the multiple blades 41 in the axial direction AR1. Each of the multiple first supports 71 has, in the axial direction AR1, a thickness that varies in a direction in which the first support 71 extends. More specifically, as shown in FIGS. 3 and 5, the thickness of each first support 71 is greatest at a position 71a at which the first support 71 connects to the first body 21, gradually smaller in the direction in which the first support 71 extends, and smallest at a position 71b at which the first support 71 connects to the first compartment 31. In other words, the multiple first supports 71 have, in the axial direction AR1, a thickness that is smaller toward the compartment 30 (the first compartment 31) in the direction in which the first supports 71 extend.

The second supports 72 are located downstream from the respective first supports 71 described above in the axial direction AR1. The second supports 72 connect to the second compartment 32. The second supports 72 are thus located downstream from the multiple blades 41 in the axial direction AR1. Unlike the first supports 71, each of the second supports 72 has, in the axial direction AR1, a thickness that is constant in a direction in which the second support 72 extends. Each second support 72 has an upstream surface defining a space S together with the downstream surface of the corresponding first support 71 in the axial direction AR1. As described above, the first supports 71 have, in the axial direction AR1, a thickness that is smaller toward the compartment 30 in the direction in which the first supports 71 extend. Thus, the range (clearance) of each space S is wider toward the compartment 30 and is narrower toward the body 20 in the axial direction AR1. The multiple blades 41 are movable in the spaces S. The second supports 72 have their upstream surfaces that come in contact with the downstream surfaces of the blades 41 to support the blades 41. Thus, a clearance at least greater than or equal to the thickness of the blades 41 in the axial direction AR1 is left near the body 20 in the spaces S.

The third supports 73 are located downstream from the respective second supports 72 described above in the axial direction AR1. Similarly to the second supports 72, the third supports 73 have, in the axial direction AR1, a thickness that is constant in a direction in which the third supports 73 extend. In other words, the second supports 72 and the third supports 73 are second portions in the supports 70 located downstream (in a second direction) from the multiple blades 41 in the axial direction AR1, and have, in the axial direction AR1, a thickness that is constant in a direction in which the supports 70 extend. The third supports 73 have their upstream surfaces in contact with the downstream surfaces of the respective second supports 72. The third supports 73 thus reinforce the strength of the second supports 72 that support the blades 41 from downstream.

### First State

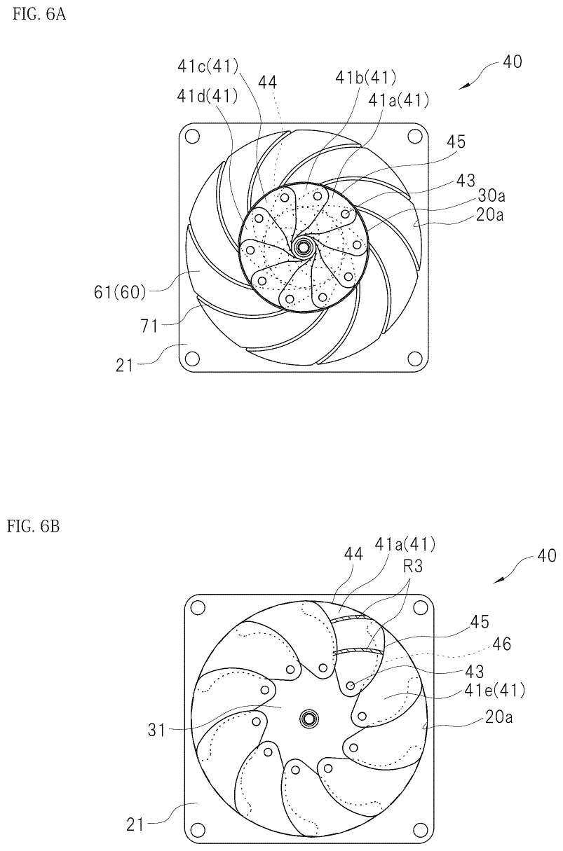

The housed state of the multiple blades 41 in the first state will now be described. FIG. 6A is a diagram of the first body 21, the first compartment 31, and the closure 40 in the first state as viewed from downstream. As shown in the figure, the second wall surface 45 is farther from the center of the opening 60 than the first wall surface 44 and the third wall surface 46 in each of the blades 41 located downstream from the first compartment 31. As described above, the first compartment 31 is sized to cover a larger area than the closure 40, and the second wall surfaces 45 extend along the circumference of the disk-shaped first compartment 31, or in other words, the outer wall surface 30a of the compartment 30, on the intersecting plane. The third wall surfaces 46 each include the curved portion 46a described above. The blades 41 and the drive 50 thus do not interfere with each other. More specifically, the curved portions 46a are closer to the circumference of the first compartment 31 than the second blade rotational shaft 53 of the second gear 52 in the drive 50 on the intersecting plane.

The shapes of the blades 41 have the above relationship with the first compartment 31 and the drive 50. Thus, none of the multiple blades 41 is exposed to the opening 60, and all the blades 41 are entirely located downstream from the first compartment 31. In other words, the blades 41 in the first state are less likely to be exposed to the opening 60 to narrow an area through which cooling air passes. The blades 41 can thus be housed without reducing the cooling efficiency of the fan device 100.

As described above, each of the multiple blades 41 includes the second area R2 raised upstream in the axial direction AR1. Thus, when the multiple blades 41 are housed in the first compartment 31, a blade 41 of the blades 41 includes the second area R2 located upstream from the first area R1 of at least one of the other blades 41 and overlapping the first area R1 in the axial direction AR1 as shown in FIGS. 5 and 6A. More specifically, as shown in FIG. 6A, a blade 41a includes the second area R2 located upstream from and overlapping the first areas R1 of a blade 41b adjacent to the blade 41a, a blade 41c adjacent to the blade 41b, and a blade 41d adjacent to the blade 41c. In other words, the blades 41a, 41b, 41c, and 41d among the ten blades 41 partially overlap one another in the axial direction AR1 and housed in the compartment 30.

Although the four blades 41a, 41b, 41c, and 41d partially overlap one another in FIGS. 5 and 6A, any number of blades 41 may overlap one another. The number of blades 41 that overlap one another may be determined as appropriate for the sizes of the backflow prevention device 10 and the opening 60. In other words, at least two blades 41 may be partially overlap each other in the axial direction AR1 and housed in the compartment 30.

The closure 40 including the multiple blades 41 that close the opening 60 can thus be housed in the compartment 30 that is located adjacent to the central portion of the opening 60 and has a smaller area than the opening 60. This increases the air tunnels through which cooling air passes, reducing a decrease in the cooling efficiency of the fan device 100. In particular, the compartment 30 is not to be located outward from the outer circumference of the opening 60. This can reduce an increase in the size of the backflow prevention device 10.

### Second State

The multiple blades 41 spread to close the opening 60 in the second state will now be described. As the second gear 52 in the first state described above rotates in a rotation direction AR2 in FIG. 3, all the first gears 51 meshing with the second gear 52 rotate in a rotation direction AR3 in FIG. 3. In response to the rotation of the first gears 51 in the rotation direction AR3, all the blades 41 rotate about the first blade rotational shafts 43 at the same time in the rotation direction AR3.

FIG. 6B is a diagram of the first body 21, the first compartment 31, and the closure 40 in the second state as viewed from downstream. The multiple blades 41 rotate, and the first wall surfaces 44 extending along the circumference of the opening 60 come in contact with the inner wall surface 20a of the body 20 that is an end of the opening 60 to close the opening 60. The blades 41 rotate to move on the intersecting plane in the spaces S between the first supports 71 and the second supports 72 described above. As described above, the range of each space S in the axial direction AR1 is narrower toward the corresponding position 71a at which the inner wall surface 20a of the body 20 and the corresponding first support 71 connect to each other. Thus, the upstream surface of each blade 41 comes in contact with the downstream surface of the corresponding first support 71 near the first wall surface 44 included in the second area R2 located upstream from the first area R1. The downstream surface 42 of each of the multiple blades 41 comes in contact with the upstream surfaces of multiple second supports 72. The multiple blades 41 are thus supported by the multiple second supports 72 from downstream. This reduces the likelihood that the multiple blades 41 in the second state vibrate in the axial direction AR1 due to vibration or air flowing from outside, thus reducing vibration and noise.

Each blade 41 includes the second area R2 raised upstream. A blade 41 of the multiple blades 41 in the second state thus partially located downstream from the first area R1 of an adjacent blade 41 and overlaps the first area R1 of the adjacent blade 41 in the axial direction AR1. More specifically, the single blade 41a includes a portion adjacent to the second wall surface 45 included in the first area R1, and the portion is located downstream from and overlaps a portion adjacent to the third wall surface 46 included in the second area R2 of the adjacent blade 41e. This reduces the likelihood that a gap is left between adjacent blades 41 to leave an area unclosed by the closure 40 in the opening 60. Flowing air is thus less likely to pass through the opening 60 in the second state.

In switching between the first state and the second state, the blades 41 rotate with their areas R3 being in contact with the first supports 71 and the second support 72, which curve and extend along the paths of the blades 41 on the intersecting plane. This reduces the likelihood that the rotating blades 41 vibrate in the axial direction AR1 and generate noise.

### Control System in Backflow Prevention Device 10

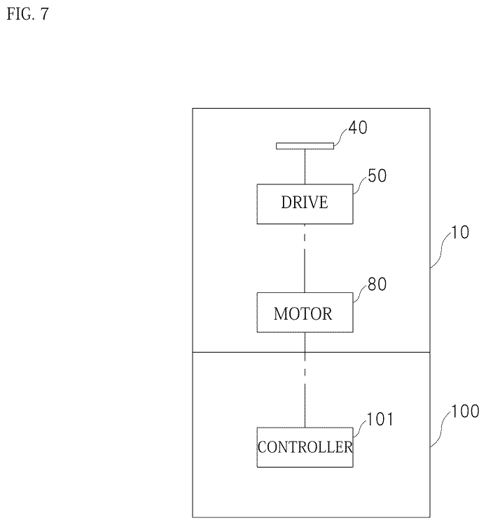

FIG. 7 is a schematic block diagram of the backflow prevention device 10 and the fan device 100 with the backflow prevention device 10 attached, showing their main components. The fan device 100 includes a controller 101. The backflow prevention device 10 includes a motor 80 as an actuator that drives the drive 50.

The controller 101 includes, for example, a central processing unit (CPU), a memory, and other components. The controller 101 reads and executes a control program prestored in a storage medium, such as a flash memory, to control various components of the fan device 100.

The controller 101 determines whether the fan device 100 has a failure based on, for example, a prestored failure diagnostic program. When detecting a failure in the fan device 100, the controller 101 outputs a first drive signal to instruct the motor 80 in the backflow prevention device 10 to switch from the first state to the second state. When the failure in the fan device 100 is eliminated by, for example, repair and a failure is no longer detected in the fan device 100, the controller 101 outputs a second drive signal to instruct the motor 80 in the backflow prevention device 10 to switch from the second state to the first state.

The motor 80 in the backflow prevention device 10 is any type of motor such as a semirotary motor. The motor 80 is connected to the second blade rotational shaft 53 of the drive 50 and located downstream from the second compartment 32. When the motor 80 is powered by a power supply (not shown) and rotates, the second blade rotational shaft 53 rotates as the motor 80 rotates.

### Operation of Backflow Prevention Device 10

In response to the first drive signal output from the controller 101, the motor 80 causes the second gear 52 to rotate about the second blade rotational shaft 53 in the rotation direction AR2 (refer to FIG. 3). In response to the rotation of the second gear 52, all the first gears 51 start rotating in the rotation direction AR3 at the same time. All the blades 41 housed in the compartment 30 thus rotate in the rotation direction AR3 (refer to FIG. 3) at the same time and spread, closing the opening 60. In response to the second drive signal output from the controller 101, the motor 80 causes the second gear 52 to rotate about the second blade rotational shaft 53 in a direction opposite the rotation direction AR2. In response to the rotation of the second gear 52, all the first gears 51 start rotating in a direction opposite the rotation direction AR3 at the same time. All the blades 41 that have been spread thus rotate in the direction opposite the rotation direction AR3 at the same time and housed in the compartment 30, unclosing the opening 60.

The structure according to the above embodiment produces at least one of the advantageous effects described below.

(1) The backflow prevention device 10 includes the compartment 30 adjacent to the central portion of the opening 60 in the body 20, the multiple blades 41 housed in the compartment 30 in a drivable manner, and the drive 50 that drives the multiple blades 41 to rotate on the intersecting plane intersecting with the axial direction AR1. The drive 50 switches the multiple blades 41 between the housed state (first state) in which the multiple blades 41 are housed in the compartment 30 and the closing state (second state) in which the multiple blades 41 close the opening 60. In the housed state, at least two of the multiple blades 41 partially overlap each other in the axial direction and are housed in the compartment. The closure 40 including the multiple blades 41 can thus be housed in the compartment 30 having a smaller area than the opening 60. This increases the air tunnels through which cooling air passes, reducing a decrease in the cooling efficiency of the fan device 100. In particular, the compartment 30 is not to be located outward from the outer circumference of the opening 60. This can reduce an increase in the size of the backflow prevention device 10.

The multiple blades 41 rotate on the intersecting plane. The blades 41 thus have a smaller movable range in the axial direction AR1 compared with a structure in which blades rotate under the pressure of backflow air, using support shafts as the pivots. The device can thus be smaller. For the multiple blades that rotate under the pressure of backflow air using the support shafts as the pivots, the blades rotate in the direction of the backflow air and thus hit the body, generating noise. The blades hitting the body adversely affect the service life of the components. In the above embodiment, the multiple blades 41 rotate on the intersecting plane. The blades 41 do not hit the body 20 while being switched to the second state, thus reducing noise. This allows the device to be quieter and to have a longer component service life.

The multiple blades 41 are driven to rotate by the drive 50. This reduces failures such as the closure not operating when the pressure of backflow air is low, unlike the structure in which the blades rotate under the pressure of backflow air using the support shafts as the pivots. Air flowing toward the electronic device can thus be blocked when the fan device 100 has a failure.

(2) Each of the multiple blades 41 includes the curved portion 46a to avoid the drive 50 in the housed state. This can reduce an increase in the size of the compartment 30 on the intersecting plane. This increases the opening 60, or in other words, the area through which cooling air passes, reducing a decrease in the cooling efficiency of the fan device 100.

For the multiple blades that rotate under the pressure of backflow air using the support shafts as the pivots, multiple sets of moving components to drive the blades are to be arranged in the opening, thus reducing the area of the opening. In the present embodiment, the drive 50 that drives the multiple blades 41 is located in the compartment 30. This reduces the likelihood that the area of the opening 60 is reduced and the likelihood that cooling air is blocked from passing through, thus reducing a decrease in the cooling efficiency of the fan device 100.

(3) The multiple supports 70 connect the body 20 and the compartment 30 on the intersecting plane and support the compartment 30. This allows the compartment 30 housing the multiple blades 41 to be located adjacent to the central portion of the opening 60. The compartment 30 is not to be located outward from the outer circumference of the opening 60, allowing the device to be smaller.

(4) Each of the multiple supports 70 extends along the path on which the corresponding blade 41 of the multiple blades 41 is driven to rotate by the drive 50 on the intersecting plane. The supports 70 can thus support the rotating blades 41 from upstream and downstream. This reduces the likelihood that the rotating blades 41 vibrate in the axial direction AR1 and generate, for example, noise, thus allowing the device to be quiet.

(5) Each of the multiple supports 70 includes the first support 71 that is the first portion located in the first direction (upstream) from the multiple blades 41 and the second support 72 and the third support 73 that are the second portions located in the second direction (downstream) from the multiple blades 41 in the axial direction, and the first direction and the second direction are aligned with the axial direction AR1. Each of the multiple supports 71 has, in the axial direction AR1, a thickness that varies in the direction in which the corresponding support 70 extends in a manner being smaller toward the compartment 30. Each of the multiple second supports 72 and third supports 73 has, in the axial direction AR1, a thickness that is constant in the direction in which the corresponding support 70 extends. Thus, while rotating or when switched to the second state, the multiple blades 41 each including the second area R2 raised upstream are supported by the first supports 71 and the second supports 72 from upstream and downstream. This reduces the likelihood that the multiple blades 41 vibrate in the axial direction AR1 due to vibration or air flowing from outside, thus reducing vibration and noise.

(6) The drive 50 includes the first gears 51 each connecting to the first blade rotational shaft 43 of the corresponding blade 41 of the multiple blades 41, and the second gear 52 meshing with the first gears 51. The second gear 52 rotates about the second blade rotational shaft 53 extending in the axial direction AR1 in the compartment 30. In this simple structure including the two types of gears, which are the first gears 51 and the second gear 52, all the multiple blades 41 can be driven to rotate at the same time. In addition, this structure reduces failures such as the closure not operating when the pressure of backflow air is low, unlike the structure in which the blades rotate under the pressure of backflow air using the support shafts as the pivots. Air flowing toward the electronic device can thus be blocked when the fan device 100 has a failure.

(7) The motor 80 rotates the second gear 52. This allows automatic switching of the backflow prevention device 10 between the first state and the second state, thus improving the user convenience.

Although various embodiments and modifications are described above, the present invention is not limited to the embodiments and the modifications. Other forms implementable within the scope of technical idea of the present invention fall within the scope of the present invention.

The drive 50 may be driven by a user operation in place of the motor 80. In this case, a user may directly operate the second gear 52 and rotate the second gear 52 in the rotation direction AR2 or in the direction opposite the rotation direction AR2. In this case, the user can operate the support shaft 54 extending in the radial direction of the second gear 52 as an operable member.

When the fan device 100 has a failure, the second gear 52 may rotate in the rotation direction AR2 to switch from the first state to the second state. In this case, the drive 50 includes an urging member, such as a helical torsion spring, that urges the second gear 52 in the rotation direction AR2, and a locking assembly that restricts (locks) the urging member from causing the second gear 52 to rotate in an urging direction. In response to the first drive signal from the controller 101 in the fan device 100, the locking assembly releases the restriction on the urging member. This causes the second gear 52 to rotate in the rotation direction AR2 under an urging force from the urging member. The blades 41 are thus spread, closing the opening 60.

The fan device 100 may discharge air heated by the electronic device outside, instead of drawing cooling air to cool the electronic device.

The technique according to one or more embodiments of the present invention may provide the structure described below.

(1) A backflow prevention device attachable to a fan device, the backflow prevention device comprising:
a body having an opening through which air passes in response to rotation of the fan device about the rotation axis, the air flowing in an axial direction in which a rotation axis of the fan device extends;
a compartment adjacent to a central portion of the opening;
a plurality of blades housed in the compartment in a drivable manner; and
a drive configured to drive the plurality of blades to rotate on an intersecting plane intersecting with the axial direction,
wherein the drive switches the plurality of blades between a housed state in which the plurality of blades are housed in the compartment and a closing state in which the plurality of blades close the opening, and
in the housed state, at least two of the plurality of blades partially overlap each other in the axial direction and are housed in the compartment.

(2) The backflow prevention device according to (1), wherein
the drive is located in the compartment, and
each of the plurality of blades includes a curved portion to avoid the drive in the housed state.

(3) The backflow prevention device according to (1) or (2), further comprising: a plurality of supports connecting the body and the compartment on the intersecting plane and supporting the compartment.

(4) The backflow prevention device according to (3), wherein
each of the plurality of supports extends along a path on which a corresponding blade of the plurality of blades is driven to rotate by the drive on the intersecting plane.

(5) The backflow prevention device according to (3) or (4), wherein
each of the plurality of supports includes, in the axial direction, a first portion located in a first direction from the plurality of blades and a second portion located in a second direction from the plurality of blades, and the first direction and the second direction are aligned with the axial direction,
the first portion has, in the axial direction, a thickness varying in a direction in which a corresponding support of the plurality of supports extends, and the thickness varies in a manner being smaller toward the compartment, and
the second portion has, in the axial direction, a thickness being constant in the direction in which the corresponding support extends.

(6) The backflow prevention device according to any one of (1) to (5), wherein
each of the plurality of blades includes a first blade rotational shaft protruding in the axial direction,
the drive includes
   a plurality of first gears each connecting to the first blade rotational shaft of a corresponding blade of the plurality of blades, and
   a second gear meshing with the plurality of first gears, and
the second gear rotates about a second blade rotational shaft extending in the axial direction in the compartment.

(7) The backflow prevention device according to (6), further comprising:
an operable member configured to rotate the second gear.

(8) The backflow prevention device according to (6), further comprising:
a motor configured to rotate the second gear.

1. A backflow prevention device attachable to a fan device, the backflow prevention device comprising:
a body having an opening through which air passes in response to rotation of the fan device about the rotation axis, the air flowing in an axial direction in which a rotation axis of the fan device extends;
a compartment adjacent to a central portion of the opening;
a plurality of blades housed in the compartment in a drivable manner; and
a drive configured to drive the plurality of blades to rotate on an intersecting plane intersecting with the axial direction,
wherein the drive switches the plurality of blades between a housed state in which the plurality of blades are housed in the compartment and a closing state in which the plurality of blades close the opening, and
in the housed state, at least two of the plurality of blades partially overlap each other in the axial direction and are housed in the compartment.

2. The backflow prevention device according to claim 1, wherein
the drive is located in the compartment, and
each of the plurality of blades includes a curved portion to avoid the drive in the housed state.

3. The backflow prevention device according to claim 2, further comprising:
a plurality of supports connecting the body and the compartment on the intersecting plane and supporting the compartment.

4. The backflow prevention device according to claim 3, wherein
each of the plurality of supports extends along a path on which a corresponding blade of the plurality of blades is driven to rotate by the drive on the intersecting plane.

5. The backflow prevention device according to claim 4, wherein
each of the plurality of supports includes, in the axial direction, a first portion located in a first direction from the plurality of blades and a second portion located in a second direction from the plurality of blades, and the first direction and the second direction are aligned with the axial direction,
the first portion has, in the axial direction, a thickness varying in a direction in which a corresponding support of the plurality of supports extends, and the thickness varies in a manner being smaller toward the compartment, and
the second portion has, in the axial direction, a thickness being constant in the direction in which the corresponding support extends.

6. The backflow prevention device according to claim 5, wherein
each of the plurality of blades includes a first blade rotational shaft protruding in the axial direction,
the drive includes
a plurality of first gears each connecting to the first blade rotational shaft of a corresponding blade of the plurality of blades, and
a second gear meshing with the plurality of first gears, and
the second gear rotates about a second blade rotational shaft extending in the axial direction in the compartment.

7. The backflow prevention device according to claim 6, further comprising:
an operable member configured to rotate the second gear.

8. The backflow prevention device according to claim 6, further comprising:
a motor configured to rotate the second gear.
